(19) United States
(12) Patent Application Publication
(10) Pub. No.: US 2012/0241639 A1
(43) Pub. Date: Sep. 27, 2012

(54) IMAGE PICKUP APPARATUS, IMAGE PICKUP SYSTEM, AND METHOD FOR CONTROLLING THE SAME

(75) Inventors: Tomoyuki Yagi, Honjo-shi (JP); Tadao Endo, Honjo-shi (JP); Toshio Kameshima, Kumagaya-shi (JP); Katsuro Takenaka, Honjo-shi (JP); Sho Sato, Kumagaya-shi (JP); Atsushi Iwashita, Honjo-shi (JP)

(73) Assignee: CANON KABUSHIKI KAISHA, Tokyo (JP)

(21) Appl. No.: 13/424,062

(22) Filed: Mar. 19, 2012

(30) Foreign Application Priority Data
Mar. 24, 2011 (JP) 2011-065982

(51) Int. Cl. H01L 27/146; G01T 1/16

(52) U.S. Cl. 250/394; 250/208.1; 250/395

(57) ABSTRACT

An image pickup apparatus includes a detector that includes a detection unit having a plurality of pixels in which conversion elements are included and a driving circuit that drives the detection unit and that executes an image pickup operation for outputting electrical signals, and a temperature control unit that includes a heating section that heats the conversion elements and that controls, before the image pickup operation begins, the temperature of the conversion elements by controlling the heating section such that the heating section heats the conversion elements in order to cause the temperature of the conversion elements before the image pickup operation begins to be higher than the temperature of the conversion elements during the image pickup operation.

### BACKGROUND OF THE INVENTION

1. Field of the Invention

The present invention relates to an image pickup apparatus, an image pickup system, and a method for controlling the image pickup apparatus, and more specifically, to a radiation imaging apparatus and a radiation imaging system that are used for still image pickup such as general image pickup and for moving image pickup such as fluoroscopy in medical treatment, and a method for controlling the radiation imaging apparatus.

2. Description of the Related Art

Currently, radiation imaging apparatuses adopting flat panel detectors (hereinafter referred to as the “detectors”) are being put to use as image pickup apparatuses for medical image diagnosis and non-destructive testing using X-rays. Such radiation imaging apparatuses are used, for example, as digital image pickup apparatuses for still image pickup such as general image pickup and moving image pickup such as fluoroscopy in medical image diagnosis. An indirect conversion detector is known in which a conversion element obtained by combining a photoelectric conversion element containing amorphous silicon and a wavelength conversion member that converts radiation into light in a wavelength band that can be detected by the photoelectric conversion element is used. A direct conversion detector is also known in which a conversion element that directly converts radiation into electric charge using a material such as amorphous selenium is used.

In such an image pickup apparatus, it is possible that dark current varies or lag is generated or varies due to application of radiation or light in the past, because dangling bonds or defects in a conversion element composed of an amorphous semiconductor can serve as trap levels. Therefore, there has been a possibility that the characteristics of the image pickup apparatus and obtained image signals vary. In U.S. Patent Application Publication No. 2008/0226031, a technique has been disclosed in which the variation in the characteristics of an image pickup apparatus and obtained image signals is suppressed by radiating light that does not carry information regarding a subject onto a detector from a light source that has been separately prepared, before radiation or light carrying the information regarding the subject is radiated onto the detector.

In the case of the technique disclosed in U.S. Patent Application Publication No. 2008/0226031, a light source and a driving unit for driving the light source need to be provided in the apparatus. In addition, in order to equalize the effects on the variation in the characteristics of a detector and obtained image signals, light radiated from the light source has to be radiated onto the detector with uniform in-plane distribution. However, in order for the light source to radiate light with uniform in-plane distribution, a power supply that supplies high operating voltage needs to be provided or a complex configuration needs to be realized, which leads to an increase in the size of the light source and the driving unit, thereby making it difficult to thin and reduce the image pickup apparatus in size. In addition, the control of the operation of the light source, such as the control of the in-plane distribution and the luminance of the light radiated from the light source, becomes complex due to deterioration of the light source, thereby making it difficult to realize simple control of the operation of the image pickup apparatus.

### SUMMARY OF THE INVENTION

In view of the above, one aspect of the present invention provides a thin, light image pickup apparatus capable of reducing variation in the characteristics of the image pickup apparatus and obtained image signals and whose operation can be controlled in a simple manner, and an image pickup system including the image pickup apparatus. An image pickup apparatus according to an aspect of the present invention includes a detector that includes a detection unit including a plurality of conversion elements that convert radiation or light into electric charges and a driving circuit that drives the detection unit to output electrical signals according to the electric charges from the detection unit, and configured to execute an image pickup operation for outputting the electrical signals, and a temperature control unit configured to include a heating section that heats the plurality of conversion elements and control, before the image pickup operation begins, temperature of the conversion elements by controlling the heating section such that the heating section heats the conversion elements in order to cause the temperature of the conversion elements before the image pickup operation to be higher than the temperature of the conversion elements during the image pickup operation.

According to embodiments of the present invention, it is possible to provide a thin, light image pickup apparatus capable of reducing variation in the characteristics of the image pickup apparatus and obtained image signals and whose operation can be controlled in a simple manner, and an image pickup system including the image pickup apparatus.

Further features of the present invention will become apparent from the following description of exemplary embodiments with reference to the attached drawings.

### BRIEF DESCRIPTION OF THE DRAWINGS

FIG. 1 is a schematic block diagram of an image pickup system according to a first embodiment of the present invention.

FIG. 2 is a diagram illustrating a schematic equivalent circuit of an image pickup apparatus according to the first embodiment of the present invention.

FIG. 3A is a characteristic diagram illustrating the time dependence of the dark current of a conversion element according to the first embodiment of the present invention.

FIG. 3B is a characteristic diagram illustrating the time dependence of the amount of lag of the conversion element according to the first embodiment of the present invention.

FIGS. 4A to 4C are timing charts of the image pickup apparatus according to the first embodiment of the present invention.

FIG. 5 is a flowchart illustrating the operation flow of the image pickup system according to the first embodiment of the present invention.

FIGS. 6A and 6B are diagrams illustrating schematic equivalent circuits of an image pickup apparatus according to a second embodiment of the present invention.

FIG. 7 is a characteristic diagram illustrating the time dependence of the amount of lag of a conversion element according to the second embodiment of the present invention.

FIGS. 8A to 8C are timing charts of the image pickup apparatus according to the second embodiment of the present invention.

FIGS. 9A and 9B are schematic block diagrams illustrating an image pickup system according to a third embodiment of the present invention.

### DESCRIPTION OF THE EMBODIMENTS

Embodiments of the present invention will be described hereinafter in detail with reference to the drawings. “Radiation” herein includes alpha rays, beta rays, gamma rays, and the like, which are beams composed of particles (including photons) emitted by radioactive decay, as well as beams having the same or higher energy, such as, for example, X-rays, particle beams, and cosmic rays.

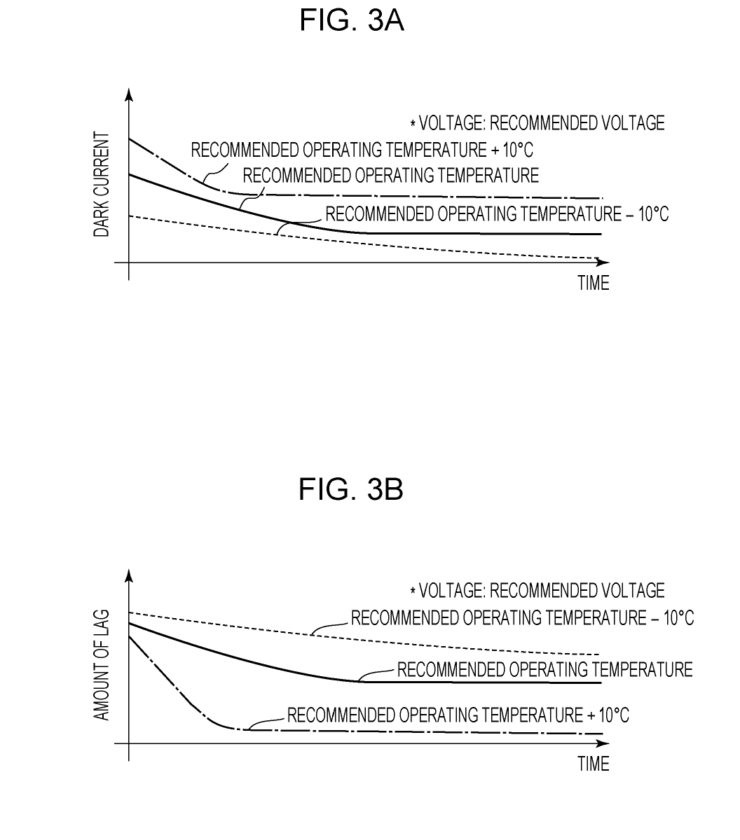

First, in order to describe the concept of a first exemplary embodiment of the present invention, the characteristics of the dark current of a conversion element according to the first exemplary embodiment will be described with reference to FIG. 3A, and the characteristics of the amount of lag of the conversion element will be described with reference to FIG. 3B. The time indicated by the horizontal axes in FIGS. 3A and 3B is the time elapsed since voltage was supplied to the conversion element. The moment immediately after the voltage is supplied corresponds to the leftmost portions of FIGS. 3A and 3B. The recommended voltage illustrated in FIGS. 3A and 3B is a recommended value of voltage to be supplied to the conversion element, and the recommended operating temperature is a recommended value of temperature of the conversion element in an image pickup operation.

The amount of lag is one indicator that determines the quality of an electrical signal output from a detector and that of image data based on the electrical signal. The lag is generated when an electrical signal based on application of radiation or light performed in an image pickup operation affects an electrical signal and image data output in a next image pickup operation. The causes of lag in a PIN photodiode, which is described below, used in the conversion element according to the present embodiment mainly include a residual electrical signal that has not been output due to an effect of the time constant relative to a switching element, and kTC noise or distributed noise generated upon output by the switching element.

The lag has a characteristic (hereinafter referred to as the “variation characteristic”) that the lag varies over time after voltage is supplied to the conversion element, and the variation characteristic is correlated with the temperature of the conversion element. The “voltage applied to the conversion element” herein refers to a potential difference between two electrodes of the conversion element. In the case of a PIN photodiode, reverse voltage is applied.

First, as illustrated in FIG. 3A, it has been found that the dark current is large immediately after voltage is supplied to the conversion element, and becomes smaller as the time elapses, finally stabilizing at a certain value. In addition, the dark current is larger when the temperature of the conversion element is higher.

As illustrated in FIG. 3B, it has been found that the amount of lag, too, is large immediately after voltage is supplied to the conversion element, and becomes smaller as the time elapses, finally stabilizing at a certain value. In addition, the amount of lag is smaller when the temperature of the conversion element is higher, and the time taken for the amount of lag to stabilize at the certain value is shorter. This can occur because the dark current is larger when the temperature is higher, and therefore the number of carriers captured by crystal defects included in the conversion element increases. Therefore, the crystal defects are filled with electric charge and the amount of lag stabilizes at early time points. The state in which the amount of lag stabilizes will be referred to as the “stable state” hereinafter.

By heating the detector before an image pickup operation begins after voltage is supplied to the conversion element in the detector, the time taken for the conversion element to enter the stable state after the voltage is supplied to the conversion element becomes shorter. Therefore, it is possible to shorten the period of an image pickup preparation operation, which is executed before the image pickup operation begins after the supply of the voltage has begun. The image pickup operation and the image pickup preparation operation are described below. In the heating of the detector, it is sufficient if the temperature becomes higher than that when the voltage is applied to the conversion element and higher than the recommended operating temperature by 10° C. to 20° C. In doing so, the same effect can be obtained with smaller power consumption than a conversion element in the related art having a light source. Here, the recommended operating temperature is a recommended temperature of the detector for outputting a signal having an appropriate signal-to-noise (S/N) ratio, namely a desired temperature in a recommended operating temperature range of 5° C. to 35° C. The temperature distribution of the detector can be easily controlled by utilizing air within a housing of the detector and metal plates and insulating substrates that are used as various supporting members. The control of the temperature distribution is easier than that of the in-plane distribution or the luminance of light performed by a light source. In addition, because of the same reason, the configuration of a unit for heating the detector can be small and light, compared to a light source and a driving unit for obtaining the same effect. Therefore, in the present invention, it is possible to provide a thin, light image pickup apparatus that is capable of reducing variation in the characteristics of the image pickup apparatus and whose operation can be controlled in a simple manner, and an image pickup system including the image pickup apparatus.

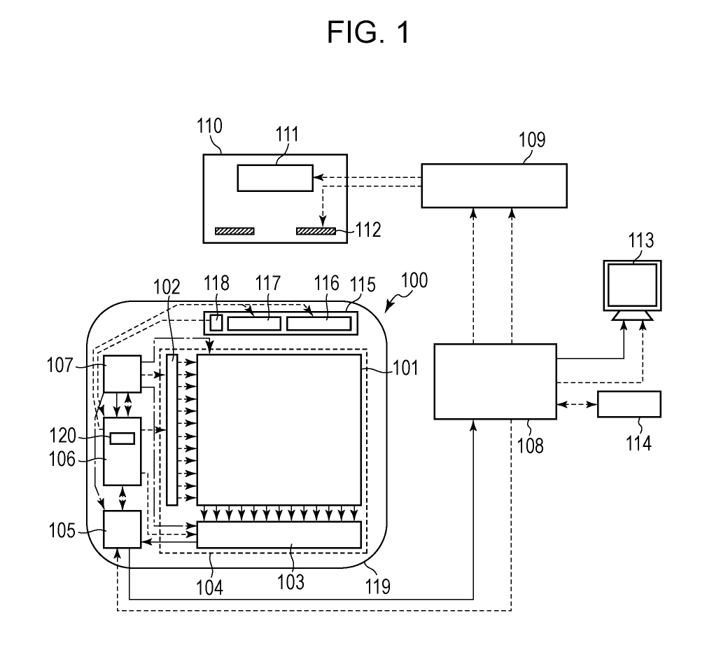

Next, a radiation imaging system according to the first embodiment will be described with reference to FIG. 1. The radiation imaging system in the present invention illustrated in FIG. 1 includes an image pickup apparatus 100, a control computer 108, a radiation control apparatus 109, a radiation generating apparatus 110, a display apparatus 113, and a control desk 114. The image pickup apparatus 100 includes a planar detector 104 having a detection unit 101 that has a plurality of pixels that convert radiation or light into electrical signals, a driving circuit 102 that drives the detection unit 101, and a read circuit 103 that outputs, as image data, the electrical signals transmitted from the detection unit 101 that has been driven. The image pickup apparatus 100 further includes a signal processing unit 105 that processes and outputs image data from the planar detector (detector) 104, a control unit 106 that controls the operation of the detector 104 by supplying a control signal to each component, and a power supply unit 107 that supplies bias to each component. The signal processing unit 105 receives a control signal from the control computer 108, which will be described later, and provides the control signal for the control unit 106. Upon receiving the control signal from the control computer 108, the control unit 106 controls at least any of the driving circuit 102, the read circuit 103, the signal processing unit 105, and the power supply unit 107. The power supply unit 107 includes a power supply circuit such as a regulator that receives voltage from an external power supply or an internal battery, which is not illustrated, and that supplies necessary voltage to the detection unit 101, the driving circuit 102, and the read circuit 103.

The control computer 108 synchronizes the radiation generating apparatus 110 and the image pickup apparatus 100, transmits a control signal for determining the state of the image pickup apparatus 100, and executes image processing for correcting, saving, and displaying image data from the image pickup apparatus 100. The control computer 108 also transmits, to the radiation control apparatus 109, a control signal for determining conditions under which radiation is applied on the basis of information from the control desk 114. The control computer 108 can obtain, on the basis of the information from the control desk 114, the time (hereinafter referred to as the “image pickup start time”) taken to begin an image pickup operation after the power supply unit 107 begins to supply voltage to the detection unit 101. The control computer 108 provides a control signal for the control unit 106 on the basis of the obtained image pickup start time.

The radiation control apparatus 109 receives control signals from the control computer 108 and controls the operation for applying radiation from a radiation source 111 included in the radiation generating apparatus 110 and the operation of a radiation field limiting mechanism 112. The radiation field limiting mechanism 112 has a function of changing a certain radiation field, which is a region of the detection unit 101 in the detector 104 to which radiation or light according to the radiation is applied. The control desk 114 receives inputs such as information regarding a subject and image pickup conditions as parameters for various types of control performed by the control computer 108, and transmits the parameters to the control computer 108. The display apparatus 113 displays image data subjected to the image processing in the control computer 108.

In addition to the detector 104, the signal processing unit 105, the control unit 106, and the power supply unit 107, the image pickup apparatus 100 according to this embodiment has a temperature control unit 115 in a housing 119 thereof. The temperature control unit 115 includes a heating section 116 that heats conversion elements in the detection unit 101, a cooling section 117 that cools the conversion elements in the detection unit 101, and a temperature detection section 118 that detects the temperature of the conversion elements in the detection unit 101. The temperature control unit 115 need not include the cooling section 117 and the temperature detection section 118, but, in view of appropriate temperature control of the pixels of the detection unit 101, the temperature control unit 115 can include the cooling section 117 and the temperature detection section 118. Before an image pickup operation is begun after supply of voltage to the conversion elements in the detection unit 101 is begun, that is, before the image pickup operation is begun, the temperature control unit 115 controls the heating section 116 such that the detection unit 101 is heated. In doing so, the time taken to cause the conversion elements to enter the stable state after the supply of voltage to the conversion elements is begun becomes shorter than in a case in which the detection unit 101 is not heated, thereby shortening the period of an image pickup preparation operation, which is executed before an image pickup operation is begun after the supply of voltage is begun. In the image pickup operation, if the temperature is higher than the recommended operating temperature, the S/N ratio might not be sufficient because of excessive dark current. In this case, when the conversion elements have entered the stable state before the image pickup operation is begun, the temperature control unit 115 can cool the detection unit 101 to achieve the recommended operating temperature. More specifically, the temperature control unit 115 judges whether or not the conversion elements in the detection unit 101 have entered the stable state, and if it has been judged that the stable state has been established, the temperature control unit 115 controls the cooling section 117 such that the detection unit 101 is cooled to achieve the recommended operating temperature in the image pickup operation. A storage area 120 is included in the control unit 106 and stores information regarding the temperature of the conversion elements and the time at which the stable state is established in advance.

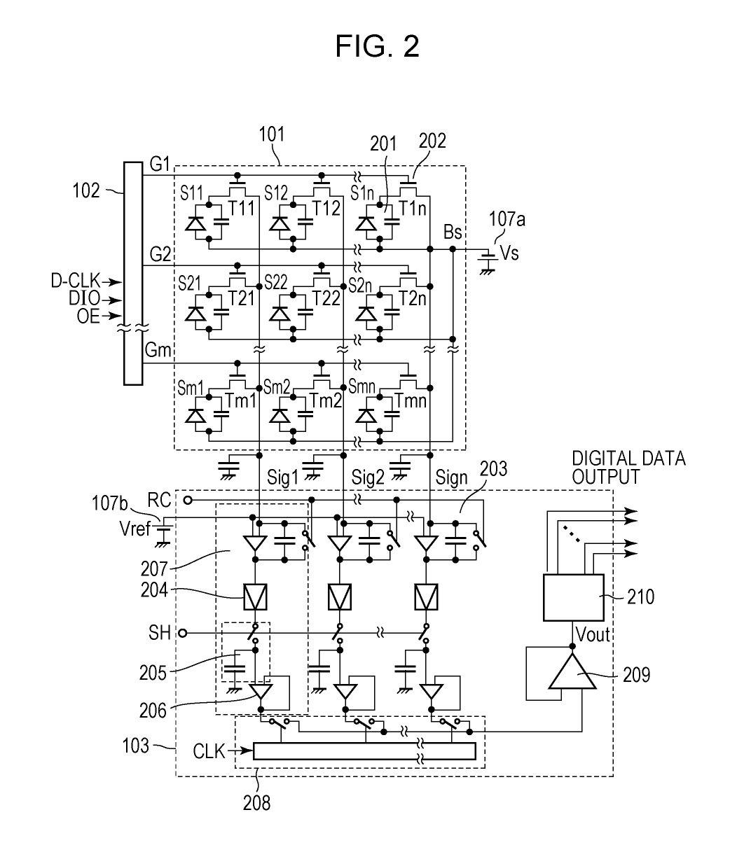

Next, the image pickup apparatus 100 according to the first embodiment of the present invention will be described with reference to FIG. 2. Components having the same configurations as those illustrated in FIG. 1 are given the same reference numerals, and therefore detailed description thereof is omitted. In FIG. 2, an image pickup apparatus including a detector that has pixels arranged in m rows and n columns is illustrated for convenience of description. Here, m and n are integers equal to or larger than 2, but an actual image pickup apparatus has much more pixels. For example, a 17-inch image pickup apparatus has pixels arranged in about 2,800 rows and 2,800 columns.

The detection unit 101 has a plurality of pixels arranged in rows and columns. The pixels each have a conversion element 201 that converts radiation or light into electric charge and a switching element 201 that outputs an electrical signal according to the electric charge. In this embodiment, a PIN photodiode that is mainly composed of amorphous silicon and that is arranged on an insulating substrate such as a glass substrate is used as a photoelectric conversion element that converts light radiated onto a conversion element into electric charge. As each conversion element 201, it is appropriate to use an indirect conversion element having a wavelength conversion member that converts radiation incident to a radiation incident side of the photoelectric conversion element into light in a wavelength band that can be detected by the photoelectric conversion element, or a direct conversion element that directly converts radiation into electric charge. As each switching element 202, it is appropriate to use a transistor having a control terminal and two main terminals, and, in this embodiment, a thin-film transistor (TFT) is used. One electrode of each conversion element 201 is electrically connected to one of the two main terminals of each switching element 202, and another electrode is electrically connected to a bias power supply 107a through a common bias wire Bs. The control terminals of a plurality of switching elements in the row direction, namely, for example, switching elements T11 to T1n, are electrically connected to the same driving wire G1 in the first row. The driving circuit 102 provides, in units of rows, driving signals for controlling the on/off state of the switching elements 202 through a driving wire. Thus, by controlling the on/off state of the switching elements 202 in units of rows using the driving circuit 102, the driving circuit 102 scans the pixels in units of rows. Other main terminals of a plurality of switching elements 202 in the column direction, namely, for example, switching elements T11 to Tm1, are electrically connected to a signal wire Sig1 in a first column. When the switching devices 202 are closed, electrical signals according to the electric charges of the conversion elements 201 are output to the read circuit 103 through signal wires. A plurality of signal wires Sig1 to Sign arranged in the column direction transmit electrical signals output from the plurality of pixels to the read circuit 103 in parallel with one another.

In the read circuit 103, an amplification circuit 207 that amplifies an electrical signal output from the detection unit 101 in parallel with other electrical signals is provided for each signal wire. Each amplification circuit 207 includes an integrating amplifier 203 that amplifier an output electrical signal, a variable amplifier 204 that amplifies an electrical signal from the integrating amplifier 203, a sample-and-hold circuit 205 that samples and holds an amplified electrical signal, and a buffer amplifier 206. The integrating amplifier 203 has an operational amplifier that amplifies and outputs a read electrical signal, an integrating capacitor, and a reset switch. The integrating amplifier 203 can change the amplification factor by changing the value of the integrating capacitor. An inverting input terminal of the operational amplifier receives an output electrical signal, a non-inverting input terminal receives reference voltage Vref from a reference power supply 107b, and an output terminal outputs an amplified electrical signal. The integrating capacitor is arranged between the inverting input terminal and the output terminal of the operational amplifier. The sample-and-hold circuit 205 is provided for each amplification circuit 207 and includes a sampling switch and a sampling capacitor. The read circuit 103 also has a multiplexer 208 that sequentially outputs, as serial image signals, electrical signals that have been read from the amplification circuits 207 in parallel with one another and a buffer amplifier 209 that outputs the image signals after executing impedance conversion. An image signal Vout, which is an analog electrical signal output from the buffer amplifier 209, is converted into digital image data by an analog-to-digital (A/D) convertor 210 and output to the signal processing unit 105 illustrated in FIG. 1. The image data processed by the signal processing unit 105 illustrated in FIG. 105 is output to the control computer 108.

The driving circuit 102 outputs, to each driving wire, a driving signal having closing voltage Vcom for causing the switching elements 202 to close or opening voltage Vss for causing the switching elements 202 to open, in accordance with a control signal (D-CLK, OE, or DIO) input from the control unit 106 illustrated in FIG. 1. Therefore, the driving circuit 102 controls the on/off state of the switching elements 202 and drives the detection unit 101.

The power supply unit 107 illustrated in FIG. 1 includes the bias power supply 107a and the reference power supply 107b for the amplification circuits 207 illustrated in FIG. 2. The bias power supply 107a supplies voltage Vs to the other electrode of each conversion element 201 through the bias wire Bs. The reference power supply 107b supplies the reference voltage Vref to the non-inverting input terminal of each operational amplifier.

The control unit 106 illustrated in FIG. 1 receives control signals from the control computer 108 or the like outside the apparatus through the signal processing unit 105, and controls the operation of the detector 104 by providing various control signals for the driving circuit 102, the power supply unit 107, and the read circuit 103. The control unit 106 controls the operation of the driving circuit 102 by providing the control signals D-CLK, OE, and DIO for the driving circuit 102. Here, the control signal D-CLK is a shift clock signal for a shift register used as a driving circuit. The control signal DIO is a pulse transferred by the shift register, and the control signal OE controls an output end of the shift register. The control unit 106 controls the operation of each component of the read circuit 103 by providing control signals RC, SH, and CLK for the read circuit 103. Here, the control signal RC controls the operation of the reset switch of the integrating amplifier 203, the control signal SH controls the operation of the sample-and-hold circuit 205, and the control signal CLK controls the operation of the multiplexer 208.

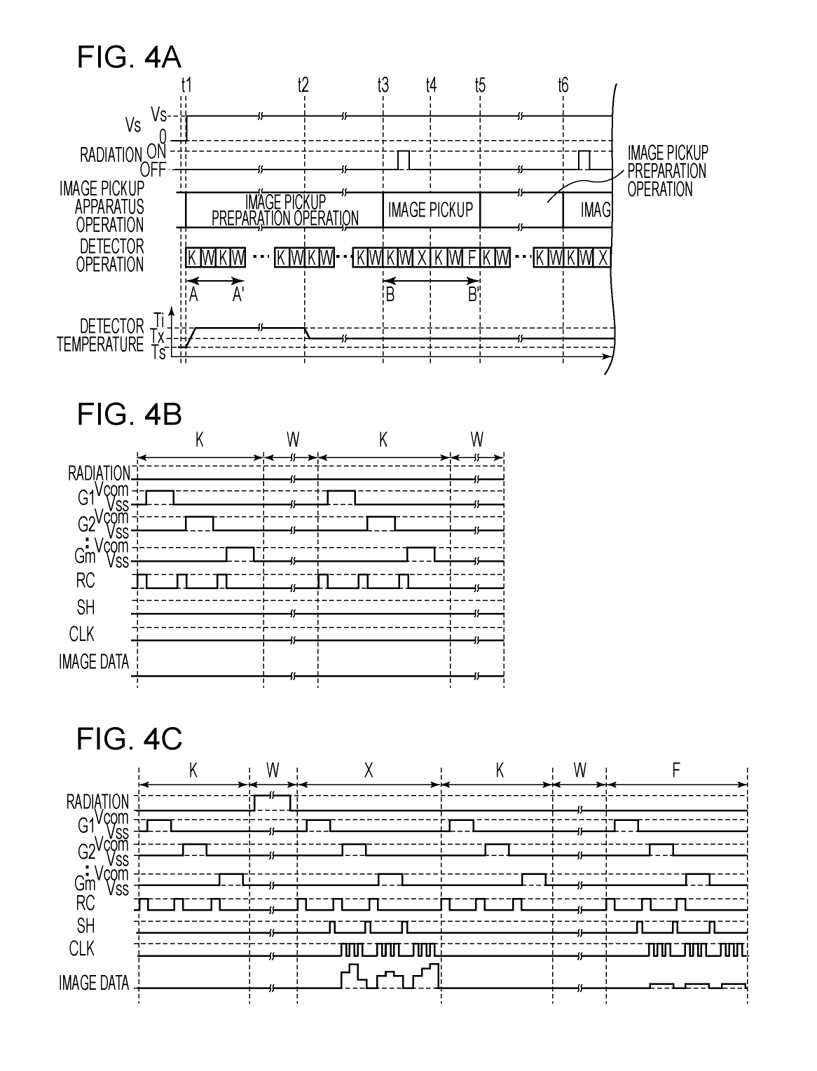

Next, the operation of the image pickup apparatus 100 according to this embodiment will be described with reference to FIGS. 4A to 4C. FIG. 4A schematically illustrates the timing at which the entirety of the image pickup apparatus 100 is driven. FIG. 4B illustrates details of a period A-A′ in FIG. 4A. FIG. 4C illustrates details of a period B-B′ in FIG. 4A.

In FIGS. 4A and 4B, when the voltage Vs has been supplied to the conversion element 201 at time t1, the image pickup apparatus 100 executes an image pickup preparation operation during an image pickup preparation period. Here, the image pickup preparation operation is an operation in which an initialization operation K is executed at least once in order to stabilize variation in the characteristics of the detector 104 due to the supply of the voltage Vs. In this embodiment, the initialization operation K is repeatedly executed for a plurality of times. The initialization operation K is an operation for initializing the conversion elements 201 by applying initial bias, which is bias before an accumulation operation, to the conversion elements 201. In FIG. 4A, a pair of operations, namely the initialization operation K and an accumulation operation W, is repeatedly executed for a plurality of times as the image pickup preparation operation. Next, at time t3, at which variation in the characteristics of the detector 104 is stabilized, the image pickup apparatus 100 begins an image pickup operation. During a period from the time t3 to time t4 in an image pickup period, which extends from the time t3 to time t5, the image pickup apparatus 100 executes the initialization operation K, the accumulation operation W, and an image output operation X. In the image pickup operation, the accumulation operation W is an operation executed in a period corresponding to application of radiation in order for the conversion elements 201 to generate electric charges. The image output operation X is an operation for outputting image data on the basis of electrical signals according to the generated electric charges. In this embodiment, the accumulation operation W in the image pickup operation is executed for the same period of time as the accumulation operation W in the image pickup preparation operation, but the present invention is not limited to this. In view of shortening the period of the image pickup preparation operation, the period of the accumulation operation W in the image pickup preparation operation can be shorter than that of the accumulation operation W in the image pickup operation. In addition, in this embodiment, in order for the conversion elements 201 to generate electric charges in a dark state, in which radiation is not applied, the accumulation operation W is executed again for the same period of time as the accumulation operation W before the image output operation X, and a dark image output operation F in which dark image data is output on the basis of the electric charges generated in the accumulation operation W is executed. In the dark image output operation F, the same operation as the image output operation X is executed in the image pickup apparatus 100. When the image pickup operation is completed at the time t5, the image pickup apparatus 100 begins the image pickup preparation operation again, and continues the image pickup preparation operation until time t6, at which the next image pickup operation is begun.

Next, the image pickup preparation operation will be described in detail with reference to FIG. 4B. As illustrated in FIG. 4B, in the initialization operation K, the control unit 106 provides the control signal RC for the reset switch in order to reset the integrating capacitor and the signal wire of each integrating amplifier 203. Next, while the voltage Vs is being applied to each conversion element 201, the driving circuit 102 applies closing voltage Vcom to the driving wire G1, thereby causing the switch elements T11 to T13 of the pixels in the first row to close. The conversion elements 201 are initialized in accordance with this closed state of the switching elements 202. At this time, the electric charges of the conversion elements 201 are output by the switching elements 202 as electrical signals, but because the control signals SH and CLK are not output and the sample-and-hold circuits 205 and the subsequent circuits are not operated in this embodiment, data according to the electrical signals is not output from the read circuit 103. The output electrical signals are then processed when the control unit 106 outputs the control signal RC again to reset the integrating capacitors and the signal wires. However, if the data is to be used for correction or the like, the control signals SH and CLK may be output and the sample-and-hold circuits 205 and the subsequent circuits may be operated in the same manner as the image output operation and the dark image output operation, which will be described later. The initialization operation K of the detection unit 101 is thus executed by controlling the on/off state of the switching elements 202 and resetting the conversion elements 201 up to an m-th row. In the initialization operation K, the reset switches may be closed at least while the switching elements 202 are closed, and resetting may be continuously executed. In addition, the period of time during which the switching elements 202 are closed in the initialization operation K may be shorter than the period of time during which the switching elements 202 are closed in the image output operation X, which will be described later. In addition, a plurality of switching elements 202 may be simultaneously closed in the initialization operation K. In such cases, it is possible to shorten the time taken to complete the whole initialization operation K, thereby making it possible to stabilize variation in the characteristics of the detector 104 earlier. It is to be noted that the initialization operation K according to this embodiment is executed in the same period as the image output operation X included in the image pickup operation, which is executed after the image pickup preparation operation. In the accumulation operation W, the opening voltage Vss is applied to the switching elements 202 while the voltage Vs is being applied to the conversion elements 201, and therefore the switching elements 202 of all the pixels are open.

Next, the image pickup operation will be described in detail with reference to FIG. 4C. Description of the operations that have been described above is omitted. As illustrated in FIG. 4C, in the image output operation, the control unit 106 first outputs the control signal RC to reset the integrating capacitors and the signal wires. Next, the driving circuit 102 applies the closing voltage Vcom to the driving wire G1 to close the switching elements T11 to T1n in the first row. Thus, electrical signals based on the electric charges generated in the conversion elements S11 to S1n in the first row are output to the signal wires Sig1 to Sign, respectively. The electrical signals output through the signal wires Sig1 to Sign in parallel with one another are amplified by the integrating amplifiers 203 and the variable amplifiers 204 in the amplification circuits 207. The amplified electrical signals are held by the sample-and-hold circuits 205, which are operated by the control signal SH, in the amplification circuits 207. After the electrical signals are held, the control unit 106 outputs the control signal RC to reset the integrating capacitors and the signals wires of the integrating amplifiers 203. After the resetting, the closing voltage Vcom is applied to a driving wire G2 in a second row as with the first row, in order to close switching elements T21 to T2n in the second row. While the switching elements T21 to T2n in the second row are closed, the multiplexer 208 sequentially outputs the electrical signals held by the sample-and-hold circuits 205 in accordance with the control signal CLK. The electrical signals from the pixels in the first row that have been read in parallel with one another are converted into serial image signals and output, and then converted into image data corresponding to one row by the A/D converter 210 and output. By executing the above operation in units of rows, namely from the first row to the m-th row, image data corresponding to one frame is output from the image pickup apparatus 100. On the other hand, in the dark image output operation F, the same operation as the image output operation X is executed by the image pickup apparatus 100 in the dark state, in which radiation is not applied.

In this embodiment, when the supply of the voltage Vs to the conversion elements 201 of the pixels is begun at the time t1, the control unit 106 controls the heating section 116 in the temperature control unit 115 such that the heating section 116 heats the pixels of the detection unit 101 to increase the temperature of the pixels from Ts to Ti. The heating by the heating section 116 is executed for at least a part of the period from the time t1 to the time t3. As the heating section 116, it is appropriate to use a component that heats and circulates the air within the housing 119 or a component that executes the heating by thermally making contact with a metal plate that mechanically holds an insulating substrate on which the conversion elements 201 are provided and whose thermal conductivity is high. The control unit 106 can control the cooling section 117 in the temperature control unit 115 such that the temperature of the pixels decreases from Ti to a recommended operating temperature Tx before the time t3, at which the image pickup preparation operation is completed and the image pickup operation is begun. In this embodiment, the temperature control unit 115 controls the cooling section 117 such that the cooling section 117 begins to cool the pixels at time t2 to decrease the temperature from Ti to the recommended operating temperature Tx. As the cooling section 117, it is appropriate to use a component that circulates the air within the housing 119 by discharging the air to the outside or a component that executes the cooling by thermally making contact with a metal plate or the insulating substrate. The temperature of the pixels of the detection unit 101 can be monitored through detection executed by the temperature detection section 118, and the control unit 106 can control at least either the heating section 116 or the cooling section 117 in accordance with the temperature of the pixels detected by the temperature detection section 118. Furthermore, if it is judged that the characteristics of the conversion elements 201 in the detection unit 101 have entered the stable state during monitoring as to whether or not the characteristics have entered the stable state, the control unit 106 can control the driving circuit 102, the read circuit 103, and the cooling section 117 such that the image pickup operation is begun. A judgment unit for executing the monitoring and making the judgment may be included in the control unit 106 or the control computer 108. In a method for monitoring and judging whether or not the stable state has been established, the control signals SH and CLK are provided for the read circuit 103 in the image pickup preparation operation illustrated in FIG. 4B as in the image pickup operation illustrated in FIG. 4C, and image data output from the detector 104 is monitored. The image data can then be compared with a certain threshold in order to make the judgment. In this case, in order to facilitate the monitoring, the multiplexer 208 can simultaneously output signals from a plurality of columns or the amplification factors of the integrating amplifier 203 and the buffer amplifier 206 can be increased, thereby expanding signals obtained from the detector 104. In addition, in order to improve the accuracy of the monitoring, the periods of the initialization operation K and the accumulation operation W in the image pickup preparation operation can be shorter than those of the initialization operation K and the accumulation operation W in the image pickup operation. This is because, in doing so, it is possible to shorten a cycle in which the image data is obtained in the image pickup preparation operation, thereby shortening the cycle of the judgment. On the other hand, the temperature and the time at which the stable state is established are measured in advance, and information regarding the temperature of the conversion elements 201 and the time at which the stable state is established is stored in the storage area 120 included in the control unit 106. The judgment unit may then judge whether or not the stable state has been established on the basis of the temperature of the conversion elements 201 in the image pickup preparation operation controlled by the temperature control unit 115, the time elapsed since the temperature control was begun by the temperature control unit 115, and the information stored in the storage area 120. More specifically, the time at which the temperature achieves a certain value through the control is compared with the time at which the stable state is established at the certain temperature stored in the storage area 120, and if the time at which the stable state is established has elapsed, it is judged that the stable state has been established. Here, the time at which the stable state is established may be determined by measuring the time at which image data becomes smaller than a certain threshold using a timer, or may be determined on the basis of the controls signals provided for the operation by which the image data has been obtained. The storage area 120 may be included in the control computer 108. These are not limited to this embodiment, and may be applied to other embodiments of the present invention.

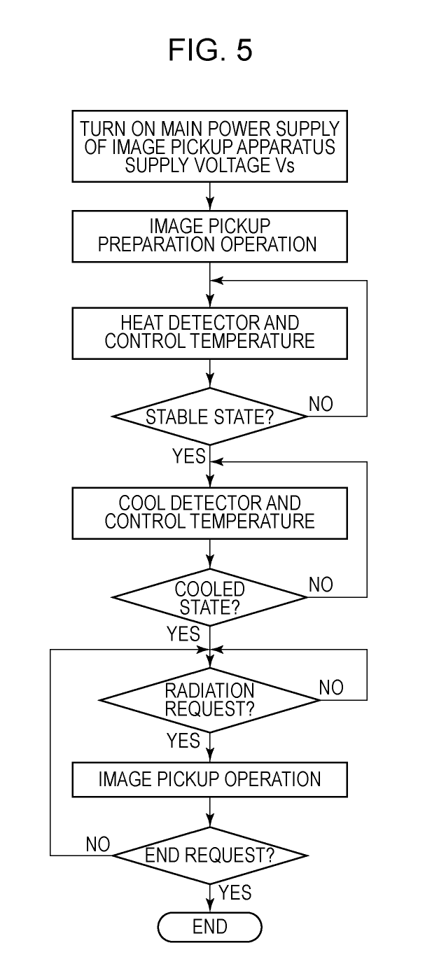

Next, the operation flow of the image pickup system according to this embodiment will be described with reference to FIG. 5. After a main power supply of the image pickup system is turned on, the control unit 106, in accordance with a request from the control computer 108, controls the power supply unit 107 such that the voltage Vs is supplied to the detection unit 101. The control unit 106 then controls the detector 104 such that the detector 104 executes the image pickup preparation operation. Next, the heating section 116 in the temperature control unit 115 heats the detection unit 101, and the temperature control unit 115 executes the temperature control such that the detection unit 101 achieves a desired temperature. Whether or not the conversion elements 201 in the detection unit 101 have entered the stable state is then judged, and if it is judged that the stable state has not been established, the temperature control is continued. On the other hand, if it is judged that the stable state has been established, the control unit 106 controls the temperature control unit 115 such that the cooling section 117 cools the detection unit 101 to achieve the recommended operating temperature, and the temperature control unit 115 executes the temperature control such that the detection unit 101 achieves a desired temperature. The temperature of the detection unit 101 is monitored by the temperature detection section 118. If the detection unit 101 has not achieved the recommended operating temperature, the control unit 106 judges that the cooling has not been completed, and the temperature control by the temperature control unit 115 is continued. When the detection unit 101 has achieved the recommended operating temperature, the control unit 106 judges that the cooling has been completed, and continues the image pickup preparation operation, waiting for a request to apply radiation.

If there is no request to apply radiation (NO), the control unit 106 controls the detector 104 such that the image pickup preparation operation is continued. If there is a request to apply radiation (YES), the control unit 106 controls the detector 104 such that the image pickup operation is executed. When the image pickup operation has been completed, if there is a request to end the series of operations (YES), the control unit 106 controls each component such that the operations end. If there is no request to end the series of operations (NO), the control unit 106 controls the detector 104 such that the detector 104 executes the image pickup preparation operation again.

### Second Embodiment

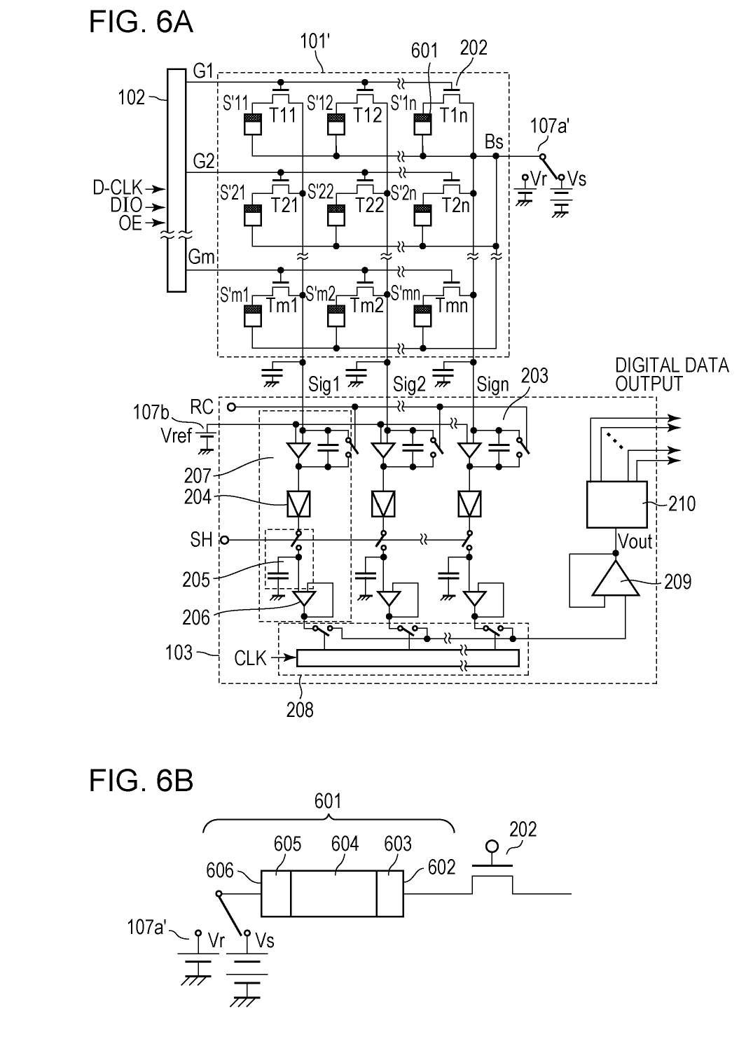

Next, an image pickup apparatus according to a second embodiment of the present invention will be described with reference to FIGS. 6A and 6B. Components having the same configurations as those according to the first embodiment illustrated in FIG. 2 are given the same reference numerals, and therefore detailed description thereof is omitted. Although an image pickup apparatus including a detector having pixels arranged in 3 rows and 3 columns is illustrated in FIG. 6A as in FIG. 2 for convenience of description, an actual image pickup apparatus has much more pixels. It is to be noted that FIG. 6B illustrates a schematic equivalent circuit of one pixel.

In the detection unit 101 according to the first embodiment, a PIN photodiode is used for a conversion element 201; however, in a detection unit 101′ according to this embodiment, a metal-insulator-semiconductor (MIS) photoelectric conversion element is used as a MIS conversion element in a conversion element 601. In addition, in the first embodiment, the other electrodes of the conversion elements 201 are electrically connected to the bias power supply 107a through the common bias wire Bs. On the other hand, in this embodiment, the other electrodes of the conversion elements 601 are electrically connected to a bias power supply 107a′ through the common bias wire Bs. The bias power supply 107a′ has a configuration with which, in addition to the voltage Vs, voltage Vr for refreshing the conversion elements 601 can be supplied to the other electrodes of the conversion elements 601.

As illustrated in FIG. 6B, in the conversion elements 601, a semiconductor layer 604 is provided between a first electrode 602 and a second electrode 606, and an insulating layer 603 is provided between the first electrode 602 and the semiconductor layer 604. In addition, an impurity semiconductor layer 605 is provided between the semiconductor layer 604 and the second electrode 606. The second electrode 606 is electrically connected to the bias power supply 107a′ through the bias wire Bs. As with the conversion elements 201, each conversion element 601 executes the accumulation operation W when the voltage Vs has been supplied to the second electrode 606 from the bias power supply 107a′ and the reference voltage Vref has been supplied to the first electrode 602 through the switching element 202. When the voltage Vr for refresh has been supplied to the second electrode 606 through the bias power supply 107a′, the conversion element 601 is refreshed by bias Vr−Vref. In this refresh, either electrons or holes of electron-hole pairs that have been generated in the semiconductor layer 604 of the MIS conversion element and that have been accumulated between the semiconductor layer 604 and the insulating layer 603 because the electron-hole pairs cannot pass through the impurity semiconductor layer 605 are moved to the second electrode 606 and vanished. The refresh will be described later in detail.

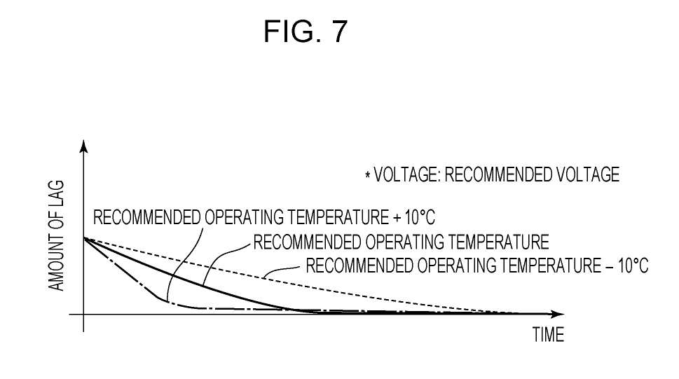

Next, the time dependence of the amount of lag of the conversion element 601 according to the second embodiment of the present invention will be described with reference to FIG. 7. The time dependence of the dark current of the conversion element 601 according to the second embodiment is substantially the same as that illustrated FIG. 3A, and therefore detailed description thereof is omitted.

As illustrated in FIG. 7, the amount of lag is large immediately after voltage is supplied to the conversion element 601, and becomes smaller as the time elapses, finally stabilizing at a certain value. In addition to the causes described in the first embodiment, there is also the following cause in the case of the MIS conversion element. In the MIS conversion element, either electrons or holes of electron-hole pairs generated by dark current or the like are accumulated between the semiconductor layer 604 and the insulating layer 603, and a potential Va of an interface between the semiconductor layer 604 and the insulating layer 603 varies in accordance with the time elapsed since the voltage was supplied to the conversion element 601. Since the potential Va varies, the voltage applied to the semiconductor layer 604 also varies. Therefore, in the case of the MIS conversion element, the sensitivity varies in accordance with the time elapsed since the voltage was supplied to the conversion element 601. This will be referred to as the “sensitivity variation” hereinafter. If the image pickup operation is executed during the sensitivity variation, either electrons or holes of electron-hole pairs generated by applied radiation or light are accumulated between the semiconductor layer 604 and the insulating layer 603 of the MIS conversion element of a pixel to which the radiation or the light has been applied, and therefore the potential Va significantly varies. On the other hand, in the MIS conversion element of a pixel to which neither radiation nor light is applied, variation in the potential Va due to the electron-hole pairs generated by radiation or light does not occur. Therefore, there is a difference in the sensitivity of the MIS conversion elements between the pixels to which radiation or light has been applied and the pixels to which neither radiation nor light has been applied. This difference in sensitivity appears as lag in image data obtained in the next image pickup operation. The lag is significant especially when the number of either electrons or holes of the electron-hole pairs accumulated between the semiconductor layer 604 and the insulating layer 603 vanished by the refresh operation is small.

On the other hand, when a sufficient number of either electron or holes of the electron-hole pairs generated by dark current or the like are accumulated between the semiconductor layer 604 and the insulating layer 603 after a lapse of sufficient time, the potential Va stabilizes at a desired value in accordance with the time elapsed since the voltage was applied to the conversion element 601. When the potential Va has stabilized, the difference in sensitivity generated by the image pickup operation becomes small and the sensitivity variation stabilizes, thereby stabilizing the sensitivity of the conversion element 601 at a desired value. This will be referred to as the “stable state”. In the stable state, variation in the potential Va due to application of light or radiation is suppressed by the refresh operation. That is, the sensitivity variation of the conversion element 601 due to application of light or radiation is suppressed and accordingly the amount of lag due to the sensitivity variation becomes small. Therefore, as illustrated in FIG. 7, the amount of lag is large immediately after the voltage is applied to the conversion element 601, and becomes smaller as the time elapses, finally stabilizing at a certain value in the stable state.

As also illustrated in FIG. 7, the higher the temperature of the conversion element 601, the shorter the time taken for the amount of lag due to the sensitivity variation to stabilize at the certain value. This is because the dark current increases as the temperature becomes higher, and accordingly the number of electron-hole pairs generated by the dark current increases. Therefore, the number of either electrons or holes of the electron-hole pairs accumulated between the semiconductor layer 604 and the insulating layer 603 increases, and the potential Va stabilizes at a desired value earlier.

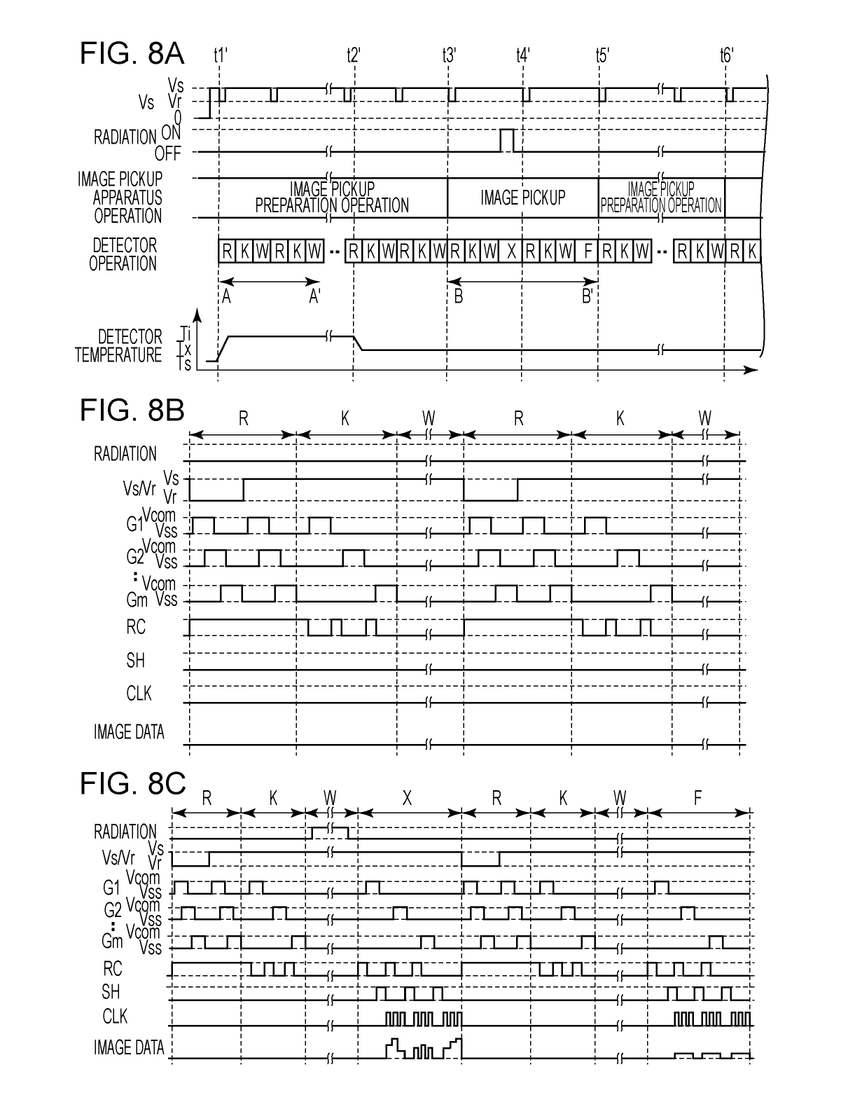

Next, the operation of the image pickup apparatus according to this embodiment will be described with reference to FIGS. 8A to 8C. FIG. 8A schematically illustrates the driving timing of the entirety of the image pickup apparatus. FIG. 8B illustrates details of a period A-A′ in FIG. 8A. FIG. 8C illustrates details of a period B-B′ in FIG. 8A. Operations that are the same as those according to the first embodiment illustrated in FIGS. 4A to 4C are given the same symbols, and therefore detailed description thereof is omitted.

The image pickup preparation operation according to the first embodiment is an operation in which the pair of the initialization operation K and the accumulation operation W is repeatedly executed for a plurality of times. However, an image pickup preparation operation according to this embodiment is an operation in which a combination between a refresh operation R, the initialization operation K, and the accumulation operation W is repeatedly executed for a plurality of times. Here, the refresh operation R is an operation for moving, to the second electrode 606, either electrons or holes of the electron-hole pairs that have been generated in the semiconductor layer 604 of the MIS conversion element and that have been accumulated between the semiconductor layer 604 and the insulating layer 603 because the electron-hole pairs cannot pass through the impurity semiconductor layer 605, and for vanishing either the electrons or the holes. In addition, the image pickup operation according to the first embodiment is an operation in which the initialization operation K, the accumulation operation W, the image output operation X, the initialization operation K, the accumulation operation W, and the dark image output operation F are executed in this order. However, an image pickup operation according to this embodiment is an operation in which the refresh operation R is further included before each initialization operation K. In the refresh operation R, first, the voltage Vr for refresh is applied to the second electrode 604 through the bias wire Bs. Next, the reference voltage Vref is applied to the first electrode 602 by closing each switching element 202, and the conversion element 601 is refreshed by the bias Vr−Vref. The plurality of conversion elements 601 are sequentially refreshed in units of rows, and the refresh of all the conversion elements 601 ends when all the switching elements 202 have been opened. Thereafter, the voltage Vs is supplied to the second electrode 606 of each conversion element 601 through the bias wire Bs, and the reference voltage Vref is supplied to the first electrode 602 by closing each switching element 202, in order to supply bias Vs−Vref to each conversion element 601. The refresh operation ends when all the conversion elements 601 have entered a bias state, in which the image pickup operation is possible, by opening all the switching elements 202. Next, the initialization operation K is executed in order to initialize the conversion elements 601 and stabilize the implicit output. The process then proceeds to the accumulation operation W.

In this embodiment, too, as in the first embodiment, it is possible to provide a thin, light image pickup apparatus that is capable of reducing variation in the characteristics of the image pickup apparatus and whose operation can be controlled in a simple manner, and an image pickup system including the image pickup apparatus.

### Third Embodiment

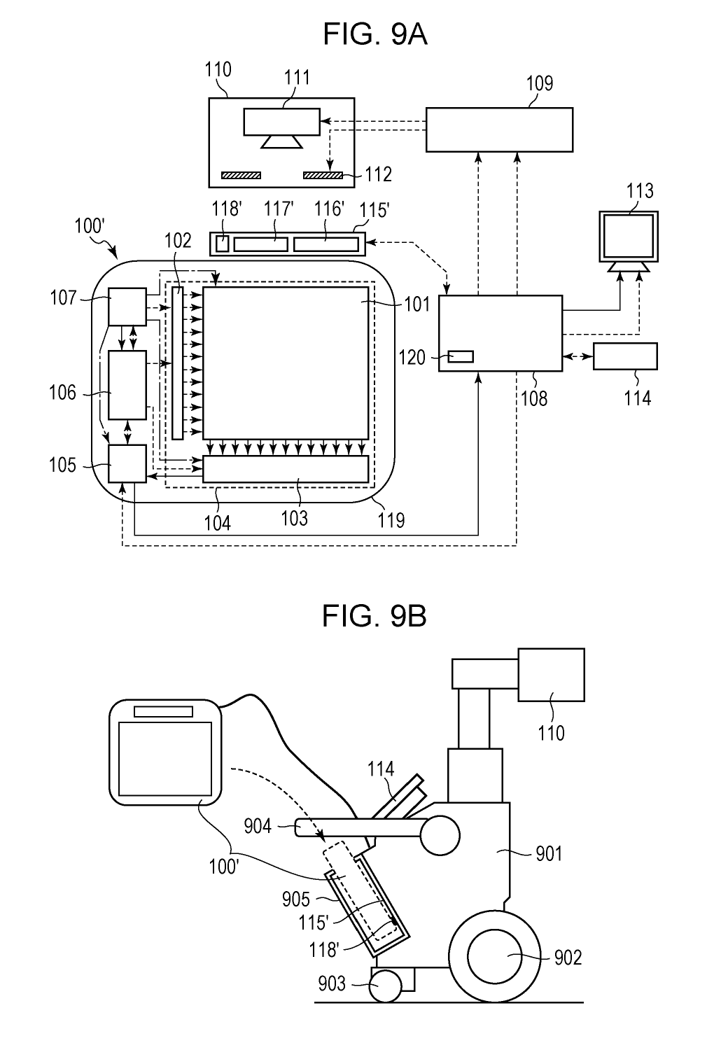

Next, an image pickup apparatus according to a third embodiment of the present invention will be described with reference to FIG. 9A. Components having the same configurations as those according to the first embodiment illustrated in FIG. 1 are given the same reference numerals, and therefore detailed description thereof is omitted.

The image pickup apparatus 100 according to the first embodiment has a configuration in which, in addition to the detector 104, the signal processing unit 105, the control unit 106, and the power supply unit 107, the temperature control unit 115 is included in the housing 119. On the other hand, as illustrated in FIG. 9A, in the case of an image pickup apparatus 100′ according to this embodiment, a temperature control unit 115′ is provided outside the housing 119. That is, a heating section 116′ heats the detection unit 101 by heating the housing 119, a cooling section 117′ cools the detection unit 101 by cooling the housing 119, and a temperature detection section 118′ detects the temperature of the detection unit 101 by detecting the temperature of the housing 119. Here, the heating section 116′ can be provided in a portion of the housing 119 on a radiation incident side corresponding to the detection unit 101. In this portion of the housing 119, a carbon substrate whose transmittance of radiation and thermal conductivity are high is used, and therefore this portion is appropriate to realize uniform heat conduction to the detection unit 101. By using such a configuration, it is possible to thin and reduce the image pickup apparatus in size, compared to the first embodiment. Each judgment and control according to this embodiment are executed by the control computer 108 through the control unit 106, but the operation of the image pickup apparatus 100′ and the temperature control unit 115′ is the same as that of the image pickup apparatus 100 and the temperature control unit 115 according to the first embodiment. The temperature control unit 115′ is provided, for example, in a bed that holds a subject in a lying imaging system or in a mechanism that holds the image pickup apparatus 100′ in an upright imaging system. The storage area 120 is included in the control computer 108.

Next, an example of the application of an image pickup system according to this embodiment will be described with reference to FIG. 9B. Components having the same configurations as those according to the first embodiment illustrated in FIG. 1 are given the same reference numerals, and therefore detailed description thereof is omitted.

FIG. 9B illustrates an example of a system using the image pickup system 100′ as a mobile radiation image pickup system 901 for doctors. Although not illustrated, the control computer 108, the radiation control apparatus 109, and the temperature control unit 115 are included in the mobile radiation image pickup system 901. The mobile radiation image pickup system 901 also has the radiation generating apparatus 110 and the control desk 114. In addition, in order to be able to move, the mobile radiation image pickup system 901 has wheels 902 and 903 and a handlebar 904. The mobile radiation image pickup system 901 also has a holding unit 905 capable of holding the image pickup apparatus 100′. In the holding unit 905, the temperature control unit 115′ and the temperature detection section 118′ included in the temperature control unit 115′ are provided in such a way as to be make contact with the image pickup apparatus 100′. The image pickup apparatus 100′ has a configuration that enables the image pickup apparatus 100′ to be held by the holding unit 905, and to be removed from the holding unit 905 when the image pickup operation is to be performed. On the other hand, when the image pickup preparation operation is to be performed, the image pickup apparatus 100′ is held by the holding unit 905, and the temperature control and the temperature detection according to the first and second embodiments can be executed by the temperature control unit 115′ provided in the holding unit 905. Each embodiment of the present invention may be realized, for example, by a computer included in the control unit 106 or by the control computer 108 by executing a program. In addition, a device for supplying a program to a computer, that is, for example, a computer-readable recording medium on which the program is recorded, such as a compact disc read-only memory (CD-ROM), or a transmission medium that transmits the program, such as the Internet, may be applied as an embodiment of the present invention. The above program may be applied as an embodiment of the present invention. The program, the recording medium, the transmission medium, and a program product are included in the scope of the present invention. Inventions that can be easily conceived by combining the first to third embodiments are also included in the scope of the present invention.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-065982 filed Mar. 24, 2011, which is hereby incorporated by reference herein in its entirety.

What is claimed is:

1. An image pickup apparatus comprising:
a detector configured to include a detection unit including a plurality of conversion elements that convert radiation or light into electric charges and a driving circuit that drives the detection unit to output electrical signals according to the electric charges from the detection unit, and configured to execute an image pickup operation for outputting the electrical signals; and
a temperature control unit configured to include a heating section that heats the plurality of conversion elements and control, before the image pickup operation begins, temperature of the conversion elements by controlling the heating section such that the heating section heats the conversion elements in order to cause the temperature of the conversion elements before the image pickup operation to be higher than the temperature of the conversion elements during the image pickup operation.

2. The image pickup apparatus according to claim 1, further comprising:
a power supply unit configured to supply voltage to the conversion elements; and
a control unit configured to control the driving circuit and the power supply unit such that the detector executes the image pickup operation and an image pickup preparation operation, which is executed before the image pickup operation begins after the power supply unit begins to supply the voltage,
wherein the temperature control unit controls the heating section such that the heating section heats the conversion elements during a period in which the image pickup preparation operation is being executed.

3. The image pickup apparatus according to claim 1,
wherein the temperature control unit further includes a cooling section that, before the image pickup operation begins, cools the conversion elements heated by the heating section.

4. The image pickup apparatus according to claim 3,
wherein the temperature control unit further includes a temperature detection section that detects the temperature of the conversion elements, and
wherein the control unit controls at least either the heating section or the cooling section in accordance with the temperature of the conversion elements detected by the temperature detection section.

5. The image pickup apparatus according to claim 1, further comprising:
a judgment unit configured to determine whether the conversion elements have entered a stable state.

6. The image pickup apparatus according to claim 5, further comprising:
a storage unit configured to store information regarding the temperature of the conversion elements and a time at which the stable state is established,
wherein the judgment unit determines whether the conversion elements have entered the stable state based on the temperature of the conversion elements controlled by the temperature control unit, a time elapsed since temperature control was begun by the temperature control unit, and the information stored in the storage unit.

7. An image pickup system comprising:
the image pickup apparatus according to claim 1; and
a control computer configured to transmit a control signal to the control unit.

8. The image pickup system according to claim 7,
wherein the image pickup apparatus has a housing in which at least the detector is included, and
wherein the temperature control unit is provided outside the housing.

9. The image pickup system according to claim 8, further comprising:
a holding unit configured to hold the image pickup apparatus,
wherein the temperature control unit is provided in the holding unit.

10. A method for controlling an image pickup apparatus including a detector including a detection unit including a plurality of conversion elements that convert radiation or light into electric charges and a driving circuit that drives the detection unit to output electrical signals according to the electric charges from the detection unit, the method comprising the steps of:
executing an image pickup operation for outputting the electrical signals; and
heating the plurality of conversion elements before the image pickup operation begins in order to cause temperature of the conversion elements before the image pickup operation begins to be higher than temperature of the conversion elements during the image pickup operation.
